(19) United States
(12) Patent Application Publication
(10) Pub. No.: US 2025/0194298 A1
(43) Pub. Date: Jun. 12, 2025

(54) SYSTEM, METHOD, AND APPARATUS FOR CONVERSION(S) IN PERIODICALLY POLED LAYERED SEMICONDUCTOR(S)

(71) Applicant: The Trustees of Columbia University in The City of New York, New York, NY (US)

(72) Inventors: CHIARA TROVATELLO, New York, NY (US); PETER JAMES SCHUCK, New York, NY (US); GIULIO CERULLO, Milano (IT); CARINO FERRANTE, L'Aquila (IT); ANDREA MARINI, L'Aquila (IT)

(21) Appl. No.: 18/973,846

(22) Filed: Dec. 9, 2024

Related U.S. Application Data
(60) Provisional application No. 63/607,309, filed on Dec. 7, 2023.

(51) Int. Cl. H10H 20/814; H10H 20/01

(52) U.S. Cl. CPC H10H 20/8142; H10H 20/017; H10H 20/019

(57) ABSTRACT

Exemplary systems, methods, and apparatuses are provided for generating at least one periodically poled layered compound. Exemplary systems, methods, and apparatuses according to an exemplary embodiment of the present disclosure can include patterning a plurality of slabs of layered compounds and stacking the plurality of slabs with each slab twisted relative to each adjacent slab.

### CROSS REFERENCE TO RELATED APPLICATION(S)

This application relates to U.S. Provisional Patent Application Ser. No. 63/607,309, filed on Dec. 7, 2023, the entire disclosure of which is incorporated herein by reference.

### STATEMENT REGARDING FEDERALLY FUNDED RESEARCH

This invention was made with government support under Award DE-SC0019443 from the US Department of Energy, Office of Science, Basic Energy Sciences. The government has certain rights in the invention.

### BACKGROUND INFORMATION

An inherent nonlinear response of matter to external electromagnetic stimuli allows light beams incident on a material to interact with each other, enabling photonic applications such as frequency conversion and the generation of non-classical states of light. Second-order nonlinear processes can be interesting, which occur in non-centrosymmetric media with χ⁽²⁾≠0 and are used to produce new light frequencies (e.g., in second harmonic, sum and difference frequency generation) and entangled photon pairs in spontaneous parametric down-conversion [see, e.g., Refs. 1 and 2].

Efficient nonlinear frequency conversion can be achieved by fulfilling the so-called phase matching (PM) condition, which implies a zero wave-vector mismatch—i.e., momentum conservation—for the interacting waves (Δk=0). For second harmonic generation (SHG),

$$Δ k = {k}_{2 ω} - 2 {k}_{ω} = \frac{2 ω}{c} ( {n}_{2 ω} - {n}_{ω} )$$

and PM requires matching the refractive indexes of the fundamental wavelength (FW), i.e., n_{ω}, and of the second harmonic (SH), n_{2ω}. Birefringent phase-matching (BPM) exploits the optical anisotropy (birefringence) of non-centrosymmetric non-linear crystals by adjusting the propagation direction inside the crystal so that the fields at ω and 2_{ω} with different polarizations experience the same refractive index. Under BPM the SH intensity I_{2ω} grows quadratically with the thickness L of the nonlinear medium. While BPM is simple and effective, it can only be applied to a limited number of crystals, such as the prototypical β-barium borate (BBO), which display moderate χ⁽²⁾ values of a few pm/V [see, e.g., Ref. 1].

There are many crystals with high nonlinearity but low anisotropy, e.g., gallium arsenide (GaAs), for which BPM is not achievable. An alternative to BPM is quasi-phase-matching (QPM), which introduces periodic phase shifts of π between the field at the FW and the one at the SH every odd multiple of the coherence length L_{c}, restoring the proper phase relationship and the quadratic growth of the SH intensity with the propagation length [see, e.g., Refs. 3 and 4]. Such a phase shift can be obtained by periodic inversion of the crystallographic orientation during material growth via molecular beam epitaxy [see, e.g., Refs. 5-7], or by cleaving the nonlinear medium slabs along the different crystal planes and diffusion-bonding them into monolithic stacks [7-9]. In ferroelectric crystals, like lithium niobate (LN, LiNbO₃) [see, e.g., Refs. 10 and 11], lithium tantalate (LiTaO₃) [see, e.g., Ref. 12] or potassium titanyl phosphate (KTP, KTiOPO₄) [see, e.g., Ref. 13], QPM can be achieved by periodic poling, i.e., by periodically inverting the sign of the nonlinear coefficient χ⁽²⁾ upon high-voltage switching of ferroelectric domains following lithographic patterning [see, e.g., Ref. 14]. The spatial modulation of χ⁽²⁾, i.e., the electrode spacing, is the so-called poling period, and it determines the wavelengths over which a certain nonlinear process can be phase matched. For LN the typical values of the poling periods are between 5 and 50 μm [see, e.g., Ref. 14] and the modulation can be extended over crystal thicknesses from millimeters to centimeters.

QPM was a breakthrough in nonlinear optics, because it has enabled the use of nonlinear crystals with large χ⁽²⁾, of the order of 10-20 pm/V, for which BPM cannot be achieved. Periodically poled LN (PPLN) crystals provide the highest conversion efficiency for waveguided SHG (I_{2ω}/I_{ω}≈70%) [see, e.g., Ref. 15], mode-locking [see, e.g., Ref. 16], optical parametric amplifiers and oscillators [see, e.g., Refs. 17-19] and entangled photon sources [see, e.g., Ref. 20]. Although standard nonlinear crystals like PPLN can achieve high nonlinear conversion efficiency and can be directly fabricated on silicon-based optical circuits, their millimeter-to-centimeter thickness L limits the number of devices that can be integrated on a single chip [see, e.g., Ref. 21].

A rise of van der Waals layered material science has opened up research on new classes of crystals including semiconducting transition metal dichalcogenides (TMDs), e.g., MoS₂, MoSe₂, WS₂ and WSe₂, which are layered materials comprising crystalline sheets with strong in-plane covalent bonds but weak van der Waals out-of-plane interactions. Their large optical nonlinearity (χ⁽²⁾=100-1000 pm/V), 10-1000× higher than standard bulk crystals, has been recently exploited to demonstrate a myriad nonlinear effects at the ultimate thickness limit in single-layer TMDs [see, e.g., Refs. 22 and 23]. However, the optical gain is still limited by the sub-nm propagation length [see, e.g., Ref. 24]. In contrast to the most common 2H crystallographic phase, which is centrosymmetric in the bulk (χ⁽²⁾=0), the 3R polytype is non-centrosymmetric (χ⁽²⁾≠0) and can be used to boost the conversion efficiency of second-order nonlinear optical processes by increasing the number of layers N in the TMD sample. Using thin 3R-MoS₂ flakes (1-6 layers), it has been shown that the SH intensity grows quadratically with the number of layers, i.e., with the thickness of the nonlinear medium (I_{SHG}∝N²) [see, e.g., Ref. 25].

However, when the number of layers is increased to ˜200-300, the wave vector mismatch Δk causes a deviation from the N² enhancement [see, e.g., Ref. 26], and the SH oscillates with the sample thickness, with a semi-period equal to the coherence length L_{c} [see, e.g., Ref. 1]. Recently the coherence length in 3R-MoS₂ has been measured at telecom wavelengths [see, e.g., Ref. 26]. At L_{c} (˜500 nm) the single-pass SHG efficiency is ˜1.5×10⁴ higher than for a monolayer (I_{2ω}/I_{ω}≈10⁻⁶), resulting in the highest conversion efficiency per unit length reported to date [see, e.g., Ref. 26]. Yet, increasing this value to achieve macroscopic nonlinear conversion efficiencies, while still preserving the micrometer thickness of TMD crystals, remains an open challenge.

Thus, it may be beneficial to provide an exemplary system and method for quasi-phase matching in van der Waals layered materials, which can overcome at least some of the deficiencies described herein above.

### SUMMARY OF EXEMPLARY EMBODIMENTS

The following is intended to be a brief summary of the exemplary embodiments of the present disclosure, and is not intended to limit the scope of the exemplary embodiments.

According to exemplary embodiments of the present disclosure, a method can provide at least one periodically-poled layered compound, by, e.g., patterning a plurality of slabs of layered compounds, and stacking the plurality of slabs with each slab twisted relative to each adjacent slab. For example, a thickness of the plurality of stacked slabs can be less than 1 cm and/or up to and including 1 cm. Interfaces of the stacked slabs can provide one or more unique optical microcavities. The unique optical microcavities can increase a conversion efficiency beyond that achievable with standard phase matching. A thickness of each of the slabs can be equal to a length desired for achieving phase matching.

In further exemplary embodiments of the present disclosure, a system can be provided to facilitate at least one periodically poled layered compound. Such exemplary system can include, e.g., an electron beam lithography system configured to pattern a plurality of slabs from one or more layered compounds, and a robotic stacking machine configured to stack the plurality of slabs with each slab being twisted relative to each adjacent slab thereof. A thickness of the plurality of stacked slabs can be less than 1 cm or up to and including 1 cm. One or more interfaces between the stacked slabs can provide one or more unique optical microcavities. The unique optical microcavities can increase a conversion efficiency beyond that achievable with standard phase matching. A thickness of each of the plurality of slabs can be equal to a length desired for achieving phase matching.

According to another exemplary embodiment of the present disclosure, a periodically poled layered compound can be provided. Such exemplary compound can include, e.g., a plurality of slabs of layered compounds, stacked with each slab twisted relative to each adjacent slab. A thickness of the plurality of stacked slabs can be less than 1 cm or up to and including 1 cm. One or more interfaces between the stacked slabs can provide one or more unique optical microcavities. The unique optical microcavities can increase a conversion efficiency beyond that achievable with standard phase matching. A thickness of each of the plurality of slabs can be equal to a length desired for achieving phase matching.

According to another exemplary embodiment of the present disclosure, an apparatus can provide at least one periodically poled layered compound. Such exemplary apparatus can include, e.g., (i) a first system configured to pattern a plurality of slabs from one or more layered compounds, and (ii) a second system configured to stack the plurality of slabs with each slab being twisted relative to each adjacent slab. The first system can include or be a lithography system, and the lithography system can includes an etching capability and/or an electron beam lithography system. The second system can includes a stacking machine, which can include a robotic stacking machine.

In some exemplary embodiments of the present disclosure, the exemplary configurations can be provided which can include a periodically poled van der Waals layered material, including a plurality of slabs patterned from a single crystal flake or from different flakes of the same material with equal thickness and equal macroscopic dipole orientation, stacked with each slab or flake twisted 180 degrees relative to each adjacent slab or flake.

According to further exemplary embodiments of the present disclosure, exemplary systems, methods, and apparatuses can be provided for creating periodically poled van der Waals layered materials with a laser cutting system or an electron beam lithography and etching system configured to patterning a plurality of slabs from a single crystal flake, and a manual or a robotic stacking machine configured to stack the slabs with each slab twisted about 180 degrees relative to each adjacent slab.

In still another exemplary embodiments of the present disclosure, exemplary systems, methods, and apparatuses can be provided for creating periodically poled van der Waals layered materials, in which the thickness of each of the plurality of slabs is equal to half the poling period needed to phase-match the desired nonlinear interaction.

The interfaces between the stacked slabs in the periodically poled van der Waals material and air or the substrate can provide a plurality of intrinsic interference effects of the electro-magnetic fields involved in the nonlinear interactions, and effectively behave as optical microcavities.

Exemplary interference effects of the electro-magnetic fields involved in the nonlinear interactions at the interfaces of the periodically poled van der Waals material and air or the substrate can increase the efficiency of the nonlinear process beyond the values that can be achieved using standard quasi-phase matching, enabling the newly discovered regime of intrinsic cavity-enhanced quasi-phase matching.

For second harmonic generation in periodically poled transition metal dichalcogenides (PPTMDs), a conversion efficiency larger by, but not limited to, e.g., an additional 50% over the one achievable with standard quasi-phase-matching is reported.

The broadband generation of photon pairs via quasi-phase-matched spontaneous parametric down-conversion from periodically poled van der Waals crystals can be obtained.

These and other objects, features and advantages of the exemplary embodiments of the present disclosure will become apparent upon reading the following detailed description of the exemplary embodiments of the present disclosure, when taken in conjunction with the accompanying claims.

### BRIEF DESCRIPTION OF THE DRAWINGS

Further objects, features and advantages of the present disclosure will become apparent from the following detailed description taken in conjunction with the accompanying Figures showing illustrative embodiments of the present disclosure, in which:

FIG. 1A is an exemplary micrograph of a var der Waals flake, e.g., a 3R-MoS₂ flake, before patterning according to an exemplary embodiment of the present disclosure;

FIG. 1B is an exemplary micrograph of a var der Waals flake, e.g., a 3R-MoS₂ flake, after electron beam lithography and etching patterning, according to an exemplary embodiment of the present disclosure;

FIG. 1C is an exemplary stacking procedure for slabs of the cut or patterned van der Waals material according to an exemplary embodiment of the present disclosure;

FIG. 1D is exemplary micrographs of each stacking step according to an exemplary embodiment of the present disclosure;

FIG. 2A is an exemplary illustration of a transmission microscope used to characterize the pump wavelength-dependent second harmonic generation from periodically poled van der Waals layered materials according to an exemplary embodiment of the present disclosure;

FIG. 2B is a series of pump wavelength-dependent normalized second harmonic maps of the PPTMD according to an exemplary embodiment of the present disclosure;

FIG. 3A is an exemplary illustration of the simulation structure of the PPTMD according to an exemplary embodiment of the present disclosure;

FIG. 3B is an exemplary graph of the measured SH enhancement for different wavelength and number of slabs according to an exemplary embodiment of the present disclosure;

FIG. 3C is an exemplary graph of the simulated SH enhancement for different wavelength and number of slabs according to an exemplary embodiment of the present disclosure;

FIG. 3D is an exemplary graph comparing wavelength dependence of enhancement between model and experiment for different number of slabs according to an exemplary embodiment of the present disclosure;

FIG. 3E is an exemplary intensity profile of the calculated SH for different slab thicknesses and number of slabs where the interference effect for the FW has been accounted according to an exemplary embodiment of the present disclosure;

FIG. 3F is an exemplary intensity profile of the calculated SH for different slab thicknesses and number of slabs where the interference effect for the FW has been removed according to an exemplary embodiment of the present disclosure;

FIG. 4A is an exemplary image of the SHG spot at 530 nm emitted from a 1.2 μm-thick PPTMD, and, and close-up images of the tunable SH from 400 nm to 625 nm according to an exemplary embodiment of the present disclosure;

FIG. 4B is an exemplary graph illustrating broadband SH conversion efficiency with tunable pump wavelength (e.g., 1200 nm-1590 nm) measured on a PPTMD with slab thickness 300 nm (QPM resonance 1460 nm) and fixed power 40 mW (e.g., peak power≈98 GW/cm²) according to an exemplary embodiment of the present disclosure;

FIG. 4C is an exemplary graph illustrating broadband SH conversion efficiency with tunable pump wavelength (e.g., 1200 nm-1590 nm) measured on a PPTMD with slab thickness 570 nm (QPM resonance 1530 nm) and fixed power 52 mW (e.g., peak power≈127 GW/cm²) according to an exemplary embodiment of the present disclosure;

FIG. 5A is an exemplary illustration of an exemplary setup used to characterize the spontaneous parametric down-conversion emission from periodically poled van der Waals layered materials according to an exemplary embodiment of the present disclosure;

FIG. 5B is an exemplary graph illustrating exemplary pump-power-dependent SPDC coincidence rates (e.g., dots) for a 4-stack PPTMD with a corresponding linear fit according to an exemplary embodiment of the present disclosure;

FIG. 5C is an exemplary graph illustrating exemplary pump-power-dependent SPDC coincidence rates (e.g., dots) for a 6-stack PPTMD with a corresponding linear fit according to an exemplary embodiment of the present disclosure;

FIG. 5D is an exemplary graph illustrating exemplary pump power dependence of the CAR peak (e.g., dots) at the zero time delay for the 4-stack PPTMD with a corresponding hyperbolic fit according to an exemplary embodiment of the present disclosure;

FIG. 5E is an exemplary graph illustrating exemplary pump power dependence of the CAR peak (e.g., dots) at the zero time delay for the 6-stack PPTMD with a corresponding hyperbolic fit according to an exemplary embodiment of the present disclosure;

FIG. 5F is an exemplary graph illustrating an exemplary nonlinear enhancement of exemplary measured photon coincidence rates versus number of slabs for the 4-stack PPTMD according to an exemplary embodiment of the present disclosure;

FIG. 5G is an exemplary graph illustrating an exemplary nonlinear enhancement of exemplary measured photon coincidence rates versus number of slabs for the 6-stack PPTMD according to an exemplary embodiment of the present disclosure; and

FIG. 6 is an illustration of an exemplary block diagram of an exemplary system in accordance with certain exemplary embodiments of the present disclosure.

Throughout the drawings, the same reference numerals and characters, unless otherwise stated, are used to denote like features, elements, components or portions of the illustrated embodiments. Moreover, while the present disclosure will now be described in detail with reference to the figures, it is done so in connection with the illustrative embodiments and is not limited by the particular embodiments illustrated in the figures and the appended claims.

### DETAILED DESCRIPTION OF EXEMPLARY EMBODIMENTS

The following description of exemplary embodiments provides non-limiting representative examples referencing numerals to particularly describe features and teachings of different exemplary aspects and exemplary embodiments of the present disclosure. The exemplary embodiments described should be recognized as capable of implementation separately, or in combination, with other exemplary embodiments from the description of the exemplary embodiments. A person of ordinary skill in the art reviewing the description of the exemplary embodiments should be able to learn and understand the different described aspects of the present disclosure. The description of the exemplary embodiments should facilitate understanding of the exemplary embodiments of the present disclosure to such an extent that other implementations, not specifically covered but within the knowledge of a person of skill in the art having read the description of embodiments, would be understood to be consistent with an application of the exemplary embodiments of the present disclosure.

Nonlinear optics can be utilized with classical and quantum sources of radiation, which are essential for both fundamental spectroscopy and optical information processing. To achieve efficient nonlinear light-matter interactions, the fulfillment of the phase matching condition can be used. Separately from birefringent phase matching that relies on perfectly matched optical anisotropies in materials, periodic poling has significantly improved nonlinear optics and commercial photonics technologies by facilitating a robust quasi-phase matching in crystals like lithium niobate that possess relatively large second-order nonlinearities 2 (10-20 pm/V). Although lithium niobate can be directly fabricated on optical circuits, reaching useful frequency conversion efficiencies uses, e.g., macroscopic thicknesses (millimeter-to-centimeter), limiting the number of crystals that can be integrated on a chip.

The exemplary systems, methods, and apparatuses according to the exemplary embodiments of the present disclosure can provide broadband quasi-phase matching in a periodically poled van der Waals semiconductor (3R-MoS₂). Due to its beneficial nonlinearity (e.g., 100-1000 pm/V), exemplary systems, methods, and apparatuses according to the exemplary embodiments of the present disclosure can achieve a significant single-pass conversion efficiency for second harmonic generation of 10⁻⁴ at telecom wavelengths, over a thickness of only 1.2 μm. Due to unique intrinsic cavity effects, the quasi-phase-matched second harmonic can surpass the usual quadratic enhancement by more than, e.g., 50%. The exemplary systems, methods, and apparatuses according to the exemplary embodiments of the present disclosure can exhibit broadband generation of photon pairs via quasi-phase-matched spontaneous parametric down-conversion. additionally, the exemplary systems, methods, and apparatuses according to the exemplary embodiments of the present disclosure can be utilized in the field of phase-matched nonlinear optics with microscopic van der Waals crystals, facilitating applications that utilize simple, ultra-compact technologies, such as, e.g., on-chip entangled photon-pair sources for integrated quantum circuitry and sensing.

The exemplary systems, methods, and apparatuses according to the exemplary embodiments of the present disclosure can bridge the gap according to background discussion using a var der Waals crystal, and specifically 3R-MoS₂, to achieve QPM in periodically poled transition metal dichalcogenides (PPTMDs). Bypassing ferroelectric high voltage switching, exemplary embodiments of the present disclosure flip the sign of the optical nonlinearity χ⁽²⁾ simply by stacking consecutive slabs with opposite dipole orientation. The huge nonlinearity of TMDs combined with QPM, according to exemplary embodiments, can unlock macroscopic single-pass conversion efficiencies for SHG larger than 10⁻⁴ at telecom wavelengths, over a thickness of only 1.2 μm, over approximately 100-fold shorter propagation lengths than standard nonlinear crystals with similar performances. In addition, the exemplary embodiments of the present disclosure can include unique cavity effects caused by internal reflection of both FW and SH inside the periodically poled structure which can increase the conversion efficiency by, but not limited to, an additional 50% over standard QPM.

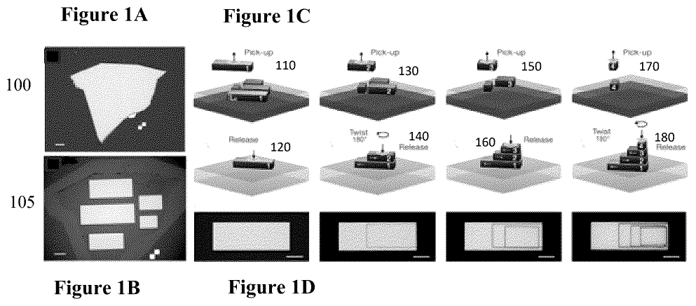

According to exemplary embodiments of the present disclosure, with the exemplary systems, methods, and apparatuses, flakes of van der Waals layered materials can be mechanically exfoliated from a bulk crystal on a reflective or transparent substrate. The thickness of the exfoliated flakes can be measured using atomic force microscopy. To fabricate the exemplary PPTMD configuration according to the exemplary embodiments of the present disclosure, it is possible to select a large flake with lateral size larger than 50 μm. FIG. 1A shows an exemplary micrograph 100 of a 3R-MoS₂ flake. Exemplary systems, methods and apparatuses can pattern the flake 100 by electron beam lithography and reactive ion etching into smaller portions. FIG. 1B shows an exemplary micrograph 110 of the 3R-MoS₂ flake after patterning. By cutting the different slabs out of a single flake 100, the exemplary systems, methods and apparatuses can facilitate that most or all areas have very similar or identical thickness(es) and the same or very similar macroscopic dipole orientation. The exemplary systems, methods and apparatuses can select a flake with, e.g., >50 μm lateral dimension and with thickness equal to half the poling period needed to phase-matched the desired nonlinear interaction. In exemplary embodiments of the present disclosure, the each slab or flake can be picked up using a dry-transfer technique.

FIG. 1C illustrates an exemplary stacking method according to the exemplary embodiment of the present disclosure. The exemplary method can start at procedure/step 110 with a patterned flake. At procedure/step 120, the largest portion of the flake (e.g., area 1) can be transferred onto a transparent substrate. At step 130, the next largest flake portion can be selected and then at procedure/step 140 it may be twisted 180 degrees and deposited on top of the first flake portion. At procedure/step 150, the next flake portion may be selected and then at step 160 deposited on top of the flake stack without twisting. At procedure/step 170, the next flake portion may be selected, and then at procedure/step 180 deposited on top of the flake stack with a 180 degree twist. This exemplary process may be followed for any number of flake portions—e.g., area 2, 3, 4, . . . n can be individually stacked on top of each other by keeping an interlayer twist angle of 180 degrees to flip the sign of χ⁽²⁾ at each semi-poling period. Exemplary microscope images of the periodically poled crystal of exemplary embodiments of the present disclosure, at each stacking step are shown in FIG. 1D.

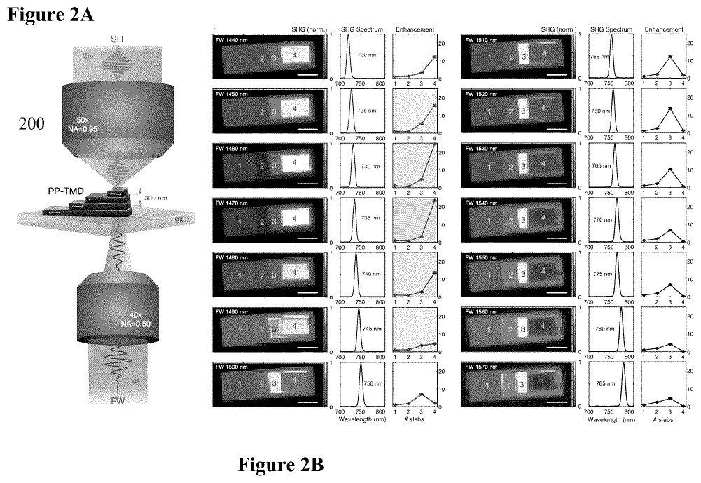

To characterize the nonlinear response of the PPTMD, the exemplary systems, methods and apparatuses according to the exemplary embodiments of the present disclosure can utilize a transmission microscope illuminated by a frequency tunable laser. FIG. 2A shows an exemplary illustration of a transmission microscope 200, where the PPTMD is excited by the FW from the back side of the SiO2 substrate with a 40× objective. The SH can be collected by a 50× objective. The exemplary systems, methods and apparatuses according to the exemplary embodiments of the present disclosure can use, e.g., a long working-distance objective or lens or optical fiber or waveguide to excite the sample. The nonlinear emission can be collected by an objective or lens or optical fiber or waveguide onto a detector.

FIG. 2B shows exemplary pump wavelength dependent normalized SH maps according to the exemplary embodiments of the present disclosure, along with the corresponding SH spectrum. For each pump wavelength, the exemplary systems, methods and apparatuses according to the exemplary embodiments of the present disclosure can extract the SH enhancement factor, i.e., the SH emission from the regions with 2, 3 and 4 slabs of the PPTMD, normalized to the SH emission of the region with 1 slab. Using the exemplary systems, methods, and apparatuses according to the exemplary embodiments of the present disclosure, peak of the SH enhancement can be obtained at SH=735 nm (FW=1470 nm), which can be the target operation wavelength for the PPTMD.

Compared to a standard first-order QPM (i.e., χ⁽²⁾ flipped in sign at each coherence length) which predicts a quadratic enhancement of 8/π, 18/π and 32/π for slab #2, #3 and #4, respectively, for SHG, the exemplary enhancement obtained by the exemplary systems, methods, and apparatuses according to the exemplary embodiments of the present disclosure is around 50% higher and not monotonically increasing with the slab number at each pump wavelength. This exemplary process, according to the exemplary embodiments of the present disclosure, may be explained considering the light interference at the different interfaces of the slabs, acting as optical microcavities and effectively providing nonlinear cavity enhancement effects.

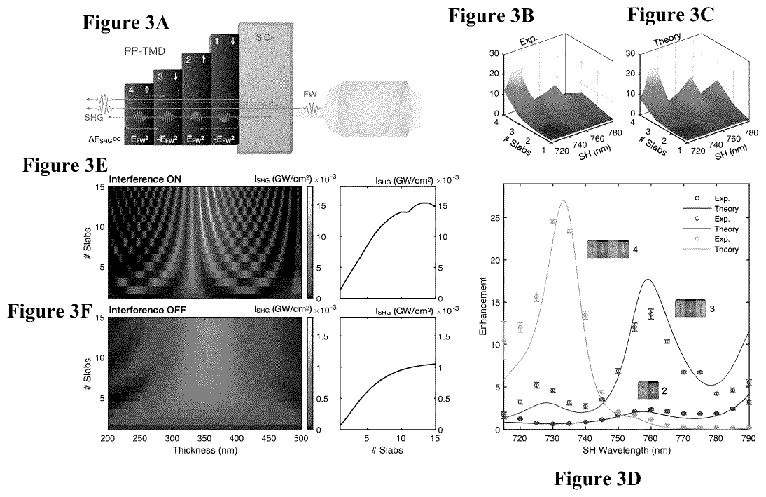

To further understand the unconventional QPM regime observed for SHG in PPTMDs, the exemplary systems, methods, and apparatuses according to the exemplary embodiments of the present disclosure can analytically model the signal by solving the coupled nonlinear equations considering the interference of FW and SH fields in the slabs, and the electric field sign inversion for the different poling conditions. For example, the exemplary systems, methods, and apparatuses according to the exemplary embodiments of the present disclosure can (i) assume that the SH process does not affect the intensity of the FW (undepleted-pump approximation), and (ii) apply the boundary conditions at the entrance and the exit of the TMD slabs to analytically retrieve the interference effects. Calculating or otherwise determining the forward and backward propagating FW electric field and considering the poling, the exemplary systems, methods and apparatuses according to the exemplary embodiments of the present disclosure can evaluate the SH in the system. In addition or alternatively, the exemplary systems, methods, and apparatuses according to the exemplary embodiments of the present disclosure can calculate the second order nonlinear polarization at 2ω in the slabs induced by FW propagation, and this term can be inserted into Maxwell's equations to extract the SH electric and magnetic fields. Applying the boundary condition for the FW and the SH, the exemplary systems, methods, and apparatuses according to the exemplary embodiments of the present disclosure can obtain the forward emitted SH intensity. The analytical calculation can be performed by exemplary embodiments assuming a normal propagation in the different slabs. An exemplary sketch of the modeled PPTMD structure according to exemplary embodiments of the present disclosure is shown in FIG. 3A, which illustrates the exemplary interference effects of FW and SH. The inversion of the electric field at each coherence length can be induced by χ⁽²⁾ flipped in sign via twist-controlled stacking of consecutive slabs.

FIGS. 3B and 3C show exemplary graphs of the exemplary measurements and the theoretical simulations of the SH enhancement factor (i.e., SH emission from slab 2, 3 and 4 normalized to the SH from slab 1) as a function of the SH wavelength and the number of slabs respectively, according to the exemplary embodiments of the present disclosure. For the theoretical simulations, the exemplary systems, methods, and apparatuses according to the exemplary embodiments of the present disclosure can use, e.g., a second order nonlinearity |χ⁽²⁾|=100 pm/V and a slab thickness of 300 nm. FIG. 3D shows an exemplary graph of an exemplary comparison between experiments and theory for poled structures with 2, 3 and 4 slabs. Such exemplary graph of FIG. 3D demonstrates a very good agreement and emphasizing the importance of an appropriate choice of slab number for each FW wavelength, to maximize the enhancement of the targeted nonlinear process, according to the exemplary embodiments of the present disclosure. In particular and according to certain exemplary embodiments of the present disclosure, for this slab thickness, an exemplary configuration with 3 slabs can provide a higher enhancement compared to the poled structure with 4 slabs for SH wavelengths above 750 nm. FIG. 3E shows an exemplary intensity profile of SH for different slab thicknesses and number of slabs generated using the exemplary systems, methods, and apparatuses according to the exemplary embodiments of the present disclosure, assuming a FW at 1450 nm (and intensity equal to 5 GW/cm2). The exemplary maximum intensity achievable as a function of the total number of slabs in the PPTMD is shown on the right, showing that interference boosts SHG, due to intrinsic cavity-induced enhancements. With various exemplary systems, methods, and apparatuses according to the exemplary embodiments of the present disclosure, it is possible show and/or provide a maximum efficiency for a slab thickness of ˜350 nm, with a strong dependence on the interference effects of the FW. The exemplary systems, methods, and apparatuses according to the exemplary embodiments of the present disclosure can also evidence the same simulation removing the interference of the FW in the slab, as illustrated in the intensity profile of FIG. 3F, which the exemplary embodiments of the present disclosure can achieve by setting the real part of refractive index of air after the slabs equal to that of the TMD. In this exemplary case, the interference pattern can be removed, obtaining a more homogeneous profile. However, the maximum efficiency can be reduced (e.g., nearly 10× lower). This exemplary comparison highlights the important role played by cavity enhancement in PPTMDs.

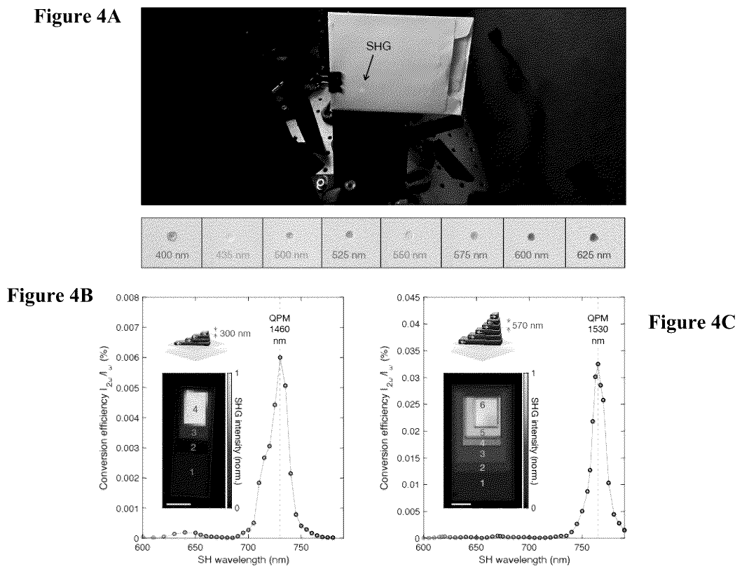

To quantitatively measure the conversion efficiency of the PPTMD samples, the exemplary systems, methods, and apparatuses according to the exemplary embodiments of the present disclosure can measure the pump wavelength dependent SH power. For example, the exemplary systems, methods, and apparatuses according to the exemplary embodiments of the present disclosure can use the frequency tunable OPO as laser source. Exemplary photographs of the broadly tunable SH spots emitted from the 1.2 km-thick PPTMD are shown in FIG. 4A, where the larger picture of the SHG spot is at 530 nm, and the close-up pictures of the tunable SH range from, e.g., 400 nm to 625 nm. Due to, e.g., the macroscopic efficiencies of PPTMDs of exemplary systems, methods, and apparatuses according to the exemplary embodiments of the present disclosure (the SH reaches ≈10 μW powers at the phase-matching bandwidth), the SH power was measured using a standard, spectrally calibrated, silicon power meter (Thorlabs S120VC). To illustrate that the exemplary systems, methods, and apparatuses according to the exemplary embodiments of the present disclosure can provide highly efficient and programmable microstacks with tunable phase matching, the SH power emitted by, e.g., two different PPTMD samples can be measured.

For example, the 4-stack PPTMD (e.g., 2 poling periods) with slab thickness of 300 nm, and a second 6-stack PPTMD (e.g., 3 poling periods) with slab thickness of 570 nm. Each sample can be excited with tunable pump wavelength and a constant pump power. FIGS. 4B and 4C show the broadband SH conversion efficiency I_{2ω}/_{ω}, i.e., SH power/FW power, with tunable pump wavelength (e.g., 1200 nm-1590 nm) and pump power of 40 mW (peak power 98 GW/cm2) and 52 mW (peak power 127 GW/cm2) respectively, measured on the PPTMD with slab thicknesses 300 nm and 570 nm, respectively. The QPM resonance is peaked at 1460 nm in FIG. 4B, and 1530 nm in FIG. 4C respectively, demonstrating QPM resonance tunability with the slab thickness, as well as validating the theoretical model that predicts, with very good agreement, the optimum slab thickness as a function of the FW wavelength.

The exemplary peak of the conversion efficiency approaches ≈10-4 (i.e., 0.01%) at FW=1460 nm for the 4-stack PPTMD (see FIG. 4B) and 0.01-0.1% at FW=1530 nm for the 6-stack PPTMD (see FIG. 4C). Exemplary systems, methods, and apparatuses according to the exemplary embodiments of the present disclosure achieve such macroscopic conversion efficiencies over a sample thickness of only 1.2 μm and 3.4 μm, respectively. PPTMDs eclipse the previous thickness-conversion efficiency trade-off curves, and now show macroscopic efficiencies over microscopic thicknesses. Additionally, to retrieve the QPM bandwidth as a function of the number of slabs in the PPTMD, exemplary systems, methods, and apparatuses according to the exemplary embodiments of the present disclosure can measure the conversion efficiency of the PPTMD phase-matched at 1530 nm from the portion of the sample with 4 and 5 slabs, and can compare it with the emission from the 6 slabs. The extracted FWHM of the QPM bandwidths can be, e.g., 22.4±1.4, 16.6±1.8 and 15.5±1.0 for the PPTMD with 4, 5 and 6 slabs, respectively. At the QPM resonance in the relevant telecom bandwidth, the extracted nonlinearity of 3R-MoS₂ is χ⁽²⁾˜100 pm/V. With higher χ⁽²⁾ compared to BBO/PPLN[1, 50], PPTMDs achieve the same efficiency, but up to 100× shorter propagation lengths.

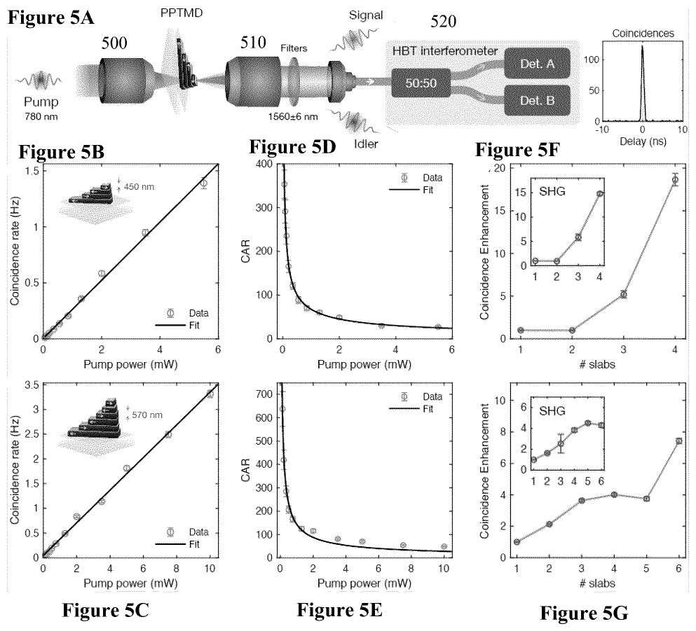

The exemplary systems, methods, and apparatuses according to exemplary embodiments of the present disclosure can use PPTMDs to demonstrate SPDC. For these exemplary measurements, exemplary systems, methods, and apparatuses according to exemplary embodiments of the present disclosure can employ two PPTMD samples quasi-phase-matched in the telecom C band. In particular, the exemplary systems, methods and apparatuses according to the exemplary embodiments of the present disclosure can use, e.g., a 4-stack PPTMD with a slab thickness of, e.g., 450 nm, giving an appropriate nonlinear enhancement at, e.g., 1560 nm, as well as the previously shown 6-stack PPTMD with a slab thickness of, e.g., 570 nm and best enhancement at, e.g., 1530 nm. To perform exemplary temporal correlation measurements in the relevant telecom wavelength range exemplary systems, methods, and apparatuses according to exemplary embodiments of the present disclosure can use a different experimental setup that is optimized for SPDC measurements. It can feature a different laser source and different detectors in a transmission geometry, as depicted in the exemplary setup of FIG. 5A. For example, FIG. 5A illustrates the use of a CW laser 500 at, e.g., 780 nm used to pump the PPTMD in a transmission geometry to filter(s) 510. As shown in in FIG. 5A, the generated SPDC photons are directed to a Hanbury Brown-Twiss (HBT) interferometer 520 for photon-pair correlation measurements via Detector A and Detector B. On the right side of FIG. 5A, the signature of photon-pair detection can be plotted, e.g., an exemplary coincidence peak at the zero delay in the arrival time histogram between the counts of two detectors.

In particular, the exemplary systems, methods, and apparatuses according to exemplary embodiments of the present disclosure can use a continuous wave 780 nm laser (e.g., TOPTICA) as a pump for the SPDC process. An aspheric lens (e.g., NA=0.68) and an objective (e.g., NA=0.85), optimized for telecom wavelengths, can be used to focus the pump onto the sample and collect the down converted light, respectively. After the PPTMD, the pump beam can be filtered out with three hard-coated long-pass filters with a cutoff wavelength of 1150 nm. Additionally, the exemplary systems, methods, and apparatuses according to exemplary embodiments of the present disclosure can use a hard-coated band pass filter at 1560 nm±6 nm, to only collect the degenerate portion of the SPDC emission. Due to chromatic aberration in the collection optics, this enhances the coincidence-to-accidental-ratio (CAR). The SPDC signal can then be coupled into a single mode fiber (e.g., SMF28, Corning). Photon pairs can be probabilistically split into two different fiber paths using a fiber-based Hanbury-Brown-Twiss interferometer, then can be guided to superconducting nanowire single-photon detectors (e.g., PhotonSpot), where detection events can be registered by a timetagger (e.g., Universal Quantum Devices). Analyzing temporal correlations of detection events yields a timing histogram, which, when detecting photon pairs generated by SPDC, is expected to show strong correlations at zero time delay between the detectors. A histogram taken in this configuration is shown on the right of FIG. 5A.

FIGS. 5B and 5C show exemplary graphs providing the exemplary coincidence rates (e.g., dots) of the 4- and 6-stack PPTMDs respectively as a function of the pump power along with corresponding linear fits. Due to the non-negligible background, accidental coincidence events are subtracted. Data points are presented as the coincidence rate averaged over the measurement time. The error bar can be calculated as the Poissonian error of total coincidence events over the whole measurement. All error bars can be calculated as the standard deviation of the measured coincidence rates. The rates follow the expected linear dependence.

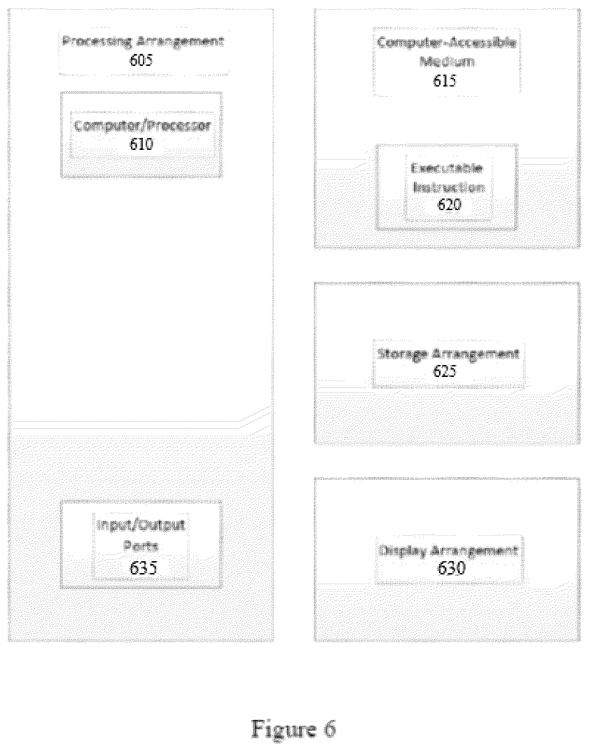

FIGS. 5D and 5E show exemplary graphs providing the exemplary pump power-dependent CAR (e.g., coincidence to accidental ratio) peak (e.g., dots) at the zero time delay for the 4-stack PPTMD illustrated in FIG. 5D and 6-stack PPTMD illustrated in FIG. 5E along with a hyperbolic fit. Data points are presented as the coincidence rate averaged over the measurement time divided by accidental coincidence events. The error bar can be calculated as the Poissonian error of total coincidence events over the whole measurement divided by accidental coincidence events. At the relevant telecom wavelength, the exemplary systems, methods, and apparatuses according to exemplary embodiments of the present disclosure can reach a maximum CAR value of, e.g., 638±75, more than one order of magnitude higher than the previously reported values in microscopic van der Waals materials at visible wavelengths, and two orders of magnitude larger at telecom wavelengths [see, e.g., Refs. 29 and 30]. Replacing the band-pass filters with broadband long-pass filters (e.g., with cutoffs at 1300 nm or 1500 nm), coincidences show a sharp correlation peak, indicating that the SPDC process is efficient over a broad spectral range.

FIGS. 5F and 5G illustrate exemplary graphs providing the relative enhancement of the coincidence rates is plotted as a function of the number of slabs in the PPTMD samples. The pump power for the plots of these figures is set to 4 mW and 12.5 mW respectively. Insets in FIGS. 5F and 5G show the trends in enhancement versus number of slabs of the measured SHG signal for 4-stack and 6-stack PPTMDs, respectively. Data points are presented as the coincidence rate averaged over the measurement time, normalized to the first data point. The error bar can be calculated as the Poissonian error of total coincidence events over the whole measurement, normalized to the first data point (slab #1). The coherence length of degenerate SPDC can be the same as that for the analogous SHG process at the same wavelengths, i.e., the conversion of telecom to visible wavelengths and vice versa, which has been shown to be, e.g., ˜500 nm [see, e.g., Ref. 31]. The exemplary systems, methods, and apparatuses according to exemplary embodiments of the present disclosure can effectuate that the coincidence rate increases with the slab number (which is proportional the thickness of the medium). Since the medium thickness exceeds the coherence length, this increase can be unambiguously attributed to quasi-phase-matching. The slight deviations from a monotonic increase in efficiency can be attributed to cavity effects from the etalonlike behavior of the PPTMDs acting on the pump and the down-converted light, as also observed for SHG. The insets show the SHG enhancement converting from, e.g., 1560 nm to 780 nm. In the 4-stack PPTMD shown in FIG. 5F, with QPM resonance exactly peaked at, e.g., 1560 nm, SPDC and SHG enhancements are in excellent agreement. The slight difference between SHG and SPDC enhancements in the 6-stack PPTMD shown in FIG. 5G can be attributed to the strong dispersion of the refractive index modulating the effective interaction length of the pump light with the material. The slab-dependent coincidence rates with broadband filtering can also illustrate a net increase of the coincidence rate, again indicating that the SPDC process is efficient over a broad spectral range, enabled by quasi-phase-matching.

Further, the exemplary systems, methods, and apparatuses according to exemplary embodiments of the present disclosure can compare the maximum coincidence rate to the brightest bulk sources. The exemplary systems, methods, and apparatuses according to exemplary embodiments of the present disclosure can utilize, as an example, the sources that have been used to generate 10-photon entanglement [see, e.g., Ref. 32]. Normalizing their reported brightness by the square of the crystal length (since the pair-generation rate scales with the interaction length squared) can yield a brightness per interaction length of, e.g., 3 MHz/W/mm². For exemplary systems, methods, and apparatuses according to exemplary embodiments of the present disclosure, a coincidence rate of ˜4.4 Hz with a pump power of, e.g., 0.5 mW, and a total crystal thickness of, e.g., 3.42 μm can be observed using broadband filtering. This gives a source brightness per length of, e.g., ˜750 MHz/W/mm², 250× larger than the best bulk SPDC sources.

Moreover, the exemplary performance of the source could be notably improved by increasing the coupling efficiency using, for example, a variety of nanofabrication technologies such as metasurfaces [see, e.g., Ref. 33]. Although the source may be comparable or exceed bulk sources in some figures of merit, it may be that the actual strength of the exemplary systems, methods, and apparatuses according to the exemplary embodiments of the present disclosure can be its compatibility with integrated on-chip components [see, e.g., Ref. 34]. In this context, producing photon pairs directly on chip will be a facilitating technology for next-generation photonic quantum devices, bypassing the loss associated with coupling each photon onto the chip [see, e.g., Ref. 35]. This loss scales exponentially with the number of photons produced. Thus, integrating PPTMDs into this environment could address a major bottleneck in photonic quantum computing.

The exemplary systems, methods, and apparatuses according to exemplary embodiments of the present disclosure can provide quasi-phase matching in periodically poled 3R-TMDs. By periodically stacking slabs of a van der Waals material with identical thickness and an interlayer twist angle of 180 degrees, exemplary systems, methods, and apparatuses according to the exemplary embodiments of the present disclosure can flip the sign of χ⁽²⁾, restoring the proper phase relationship between the fields involved in the nonlinear interaction. Due to the large nonlinearity of 3R-TMDs (100-1000 pm/V), the exemplary systems, methods, and apparatuses according to the exemplary embodiments of the present disclosure can facilitate a record single-pass second harmonic conversion efficiency at telecom wavelengths, over a thickness of only, e.g., 1.2 μm (e.g., two poling periods). Moreover, in the phase-matched interaction, the exemplary systems, methods, and apparatuses according to the exemplary embodiments of the present disclosure can observe nonlinear enhancement which surpasses by more than 50%, the usual quadratic enhancement typically observed in standard quasi-phase-matched crystals. This can be attributed to unique cavity effects of exemplary systems, methods, and apparatuses according to the exemplary embodiments of the present disclosure, which enhance the field overlap inside the periodically poled structure.

Theoretical simulations can accurately reproduce the conditions for such an unconventional quasi-phase matching, and predict the optimal slab thickness as a function of the desired operation wavelengths. Using the exemplary systems, methods, and apparatuses according to the exemplary embodiments of the present disclosure, the periodic poling process is potentially scalable as it can be automatized using a robotic stacking machine[see, e.g., Ref. 28]. By providing a macroscopic nonlinear gain over microscopic thicknesses, the exemplary systems, methods, and apparatuses according to the exemplary embodiments of the present disclosure set the foundation of microscopic periodic poling, establishing new ways to design nonlinear optical devices. PPTMDs according to exemplary embodiments of the present disclosure finally bridge macroscopic and microscopic nonlinear optics, providing macroscopic nonlinear gain over microscopic thicknesses. Using the exemplary systems, methods, and apparatuses according to the exemplary embodiments of the present disclosure, a capability for phase-matched nonlinear optics can be provided at the nanoscale to facilitate new quantum photonic circuitry, such as, e.g., the facile generation of entangled photon pairs in a microscopic van der Waals crystal directly embedded on chip.

For example, a broadband generation of photon pairs via quasi-phase-matched spontaneous parametric down-conversion from periodically poled van der Waals crystals can also be effectuated. An exemplary enhancement of the spontaneous parametric down-conversion emission at the QPM resonance from a PPTMD with 4 slabs compared to 1 slab is ˜20, similar to the obtained SH enhancement.

FIG. 6 shows a block diagram of an exemplary embodiment of a system according to the present disclosure. For example, exemplary procedures in accordance with the present disclosure described herein can be performed by a processing arrangement and/or a computing arrangement (e.g., computer hardware arrangement) 605. Such processing/computing arrangement 605 can be, for example entirely or a part of, or include, but not limited to, a computer/processor 610 that can include, for example one or more microprocessors, and use instructions stored on a computer-accessible medium (e.g., RAM, ROM, hard drive, or other storage device).

As shown in FIG. 6, for example a computer-accessible medium 615 (e.g., as described herein above, a storage device such as a hard disk, floppy disk, memory stick, CD-ROM, RAM, ROM, etc., or a collection thereof) can be provided (e.g., in communication with the processing arrangement 605). The computer-accessible medium 615 can contain executable instructions 620 thereon. In addition or alternatively, a storage arrangement 625 can be provided separately from the computer-accessible medium 615, which can provide the instructions to the processing arrangement 605 so as to configure the processing arrangement to execute certain exemplary procedures, processes, and methods, as described herein above, for example.

Further, the exemplary processing arrangement 605 can be provided with or include an input/output ports 635, which can include, for example a wired network, a wireless network, the internet, an intranet, a data collection probe, a sensor, etc. As shown in FIG. 6, the exemplary processing arrangement 605 can be in communication with an exemplary display arrangement 630, which, according to certain exemplary embodiments of the present disclosure, can be a touch-screen configured for inputting information to the processing arrangement in addition to outputting information from the processing arrangement, for example. Further, the exemplary display arrangement 630 and/or a storage arrangement 625 can be used to display and/or store data in a user-accessible format and/or user-readable format.

According to exemplary embodiments of the present disclosure, numerous specific details have been set forth. It is to be understood, however, that implementations of the disclosed technology can be practiced without these specific details. In other instances, well-known methods, structures and techniques have not been shown in detail in order not to obscure an understanding of this description. References to “some examples,” “other examples,” “one example,” “an example,” “various examples,” “one embodiment,” “an embodiment,” “some embodiments,” “example embodiment,” “various embodiments,” “one implementation,” “an implementation,” “example implementation,” “various implementations,” “some implementations,” etc., indicate that the implementation(s) of the disclosed technology so described may include a particular feature, structure, or characteristic, but not every implementation necessarily includes the particular feature, structure, or characteristic. Further, repeated use of the phrases “in one example,” “in one exemplary embodiment,” or “in one implementation” does not necessarily refer to the same example, exemplary embodiment, or implementation, although it may.

As used herein, unless otherwise specified the use of the ordinal adjectives “first,” “second,” “third,” etc., to describe a common object, merely indicate that different instances of like objects are being referred to, and are not intended to imply that the objects so described must be in a given sequence, either temporally, spatially, in ranking, or in any other manner.

While certain implementations of the disclosed technology have been described in connection with what is presently considered to be the most practical and various implementations, it is to be understood that the disclosed technology is not to be limited to the disclosed implementations, but on the contrary, is intended to cover various modifications and equivalent arrangements included within the scope of the appended claims. Although specific terms are employed herein, they are used in a generic and descriptive sense only and not for purposes of limitation.

The foregoing merely illustrates the principles of the disclosure. Various modifications and alterations to the described embodiments will be apparent to those skilled in the art in view of the teachings herein. It will thus be appreciated that those skilled in the art will be able to devise numerous systems, arrangements, and procedures which, although not explicitly shown or described herein, embody the principles of the disclosure and can be thus within the spirit and scope of the disclosure. Various different exemplary embodiments can be used together with one another, as well as interchangeably therewith, as should be understood by those having ordinary skill in the art. In addition, certain terms used in the present disclosure, including the specification and drawings, can be used synonymously in certain instances, including, but not limited to, for example, data and information. It should be understood that, while these words, and/or other words that can be synonymous to one another, can be used synonymously herein, that there can be instances when such words can be intended to not be used synonymously. Further, to the extent that the prior art knowledge has not been explicitly incorporated by reference herein above, it is explicitly incorporated herein in its entirety. All publications referenced are incorporated herein by reference in their entireties.

Throughout the disclosure, the following terms take at least the meanings explicitly associated herein, unless the context clearly dictates otherwise. The term “or” is intended to mean an inclusive “or.” Further, the terms “a,” “an,” and “the” are intended to mean one or more unless specified otherwise or clear from the context to be directed to a singular form.

This written description uses examples to disclose certain implementations of the disclosed technology, including the best mode, and also to enable any person skilled in the art to practice certain implementations of the disclosed technology, including making and using any devices or systems and performing any incorporated methods.

### EXEMPLARY REFERENCES

The following references are hereby incorporated by reference, in their entireties:
[1] R. W. Boyd, Nonlinear Optics, Academic Press, Elsevier, (2020).
[2] Y. Shih, An introduction to quantum optics: Photon and biphoton physics (2016).
[3] M. M. Fejer, D. H. Jundt, R. L. Byer, and G. A. Magel, IEEE Journal of Quantum Electronics 28 (1992), ISSN 15581713.
[4] L. E. Myers, R. C. Eckardt, M. M. Fejer, R. L. Byer, W. R. Bosenberg, and J. W. Pierce, Journal of the Optical Society of America B 12 (1995), ISSN 0740-3224.
[5] S. Koh, T. Kondo, T. Ishiwada, C. Iwamoto, H. Ichinose, H. Yaguchi, T. Usami, Y. Shiraki, and R. Ito, Japanese Journal of Applied Physics, Part 2: Letters 37 (1998), ISSN 00214922.
[6] L. A. Eyres, P. J. Tourreau, T. J. Pinguet, C. B. Ebert, J. S. Harris, M. M. Fejer, L. Becouarn, B. Gerard, and E. Lallier, Applied Physics Letters 79 (2001), ISSN 00036951.
[7] A. Grisard, F. Gutty, E. Lallier, B. G'erard, and J. Jimenez, Physica Status Solidi (C) Current Topics in Solid State Physics 9 (2012), ISSN 18626351.
[8] L. Gordon, G. L. Woods, R. C. Eckardt, R. R. Route, R. S. Feigelson, M. M. Fejer, and R. L. Byer, Electronics Letters 29 (1993), ISSN 00135194.
[9] R. Tanimoto, Y. Takahashi, and I. Shoji, Journal of the Optical Society of America B 38 (2021), ISSN 0740-3224.
[10] D. Feng, N. B. Ming, J. F. Hong, Y. S. Yang, J. S. Zhu, Z. Yang, and Y. N. Wang, Applied Physics Letters 37 (1980), ISSN 00036951.
[11] A. Feisst and P. Koidl, Applied Physics Letters 47 (1985), ISSN 00036951.
[12] S. Matsumoto, E. J. Lim, H. M. Hertz, and M. M. Fejer, Electronics Letters 27 (1991), ISSN 00135194.
[13] C. J. V. D. Poel, J. D. Bierlein, J. B. Brown, and S. Colak, Applied Physics Letters 57 (1990), ISSN 00036951.
[14] D. S. Hum and M. M. Fejer (2007).
[15] S. Santos, C. E. R\ddot{ } uter, D. Br\ddot{ } uske, and D. Kip, Opt. Express 29, 11386 (2021).
[16] Q. Guo, R. Sekine, J. A. Williams, B. K. Gutierrez, R. M. Gray, L. Ledezma, L. Costa, A. Roy, S. Zhou, M. Liu, et al. (2023), 2306.05314.
[17] L. E. Myers and W. R. Bosenberg, IEEE Journal of Quantum Electronics 33 (1997), ISSN 00189197.
[18] S. T. Yang and S. P. Velsko, Opt. Lett. 24, 133 (1999).
[19] J. Lu, A. A. Sayem, Z. Gong, J. B. Surya, C.-L. Zou, and H. X. Tang, Optica 8, 539 (2021).
[20] A. S. Solntsev, P. Kumar, T. Pertsch, A. A. Sukhorukov, and F. Setzpfandt, APL Photonics 3 (2018), ISSN 23780967.
[21] Q. Guo, R. Sekine, L. Ledezma, R. Nehra, D. J. Dean, A. Roy, R. M. Gray, S. Jahani, and A. Marandi, Nature Photonics 16, 625 (2022).
[22] X. Wen, Z. Gong, and D. Li, INfoMat 1,317 (2019).
[23] O. Dogadov, C. Trovatello, B. Yao, G. Soavi, and G. Cerullo, Laser & Photonics Reviews 16, 2100726 (2022).
[24] C. Trovatello, A. Marini, X. Xu, C. Lee, F. Liu, N. Curreli, C. Manzoni, S. Dal Conte, K. Yao, A. Ciattoni, et al., Nature Photonics 15, 6 (2021).
[25] M. Zhao, Z. Ye, R. Suzuki, Y. Ye, H. Zhu, J. Xiao, Y. Wang, Y. Iwasa, and X. Zhang, Light: Science & Applications 5, e16131 (2016).
[26] X. Xu, C. Trovatello, F. Mooshammer, Y. Shao, S. Zhang, K. Yao, D. N. Basov, G. Cerullo, and P. J. Schuck, Nature Photonics 16 (2022), ISSN 17494893.
[27] H. Hong, C. Huang, C. Ma, J. Qi, C. Liu, S. Wu, Z. Sun, E. Wang, and K. Liu, Twist-phase-matching in two-dimensional materials (2023), 2305.11511.
[28] A. J. Mannix, A. Ye, S. H. Sung, A. Ray, F. Mujid, C. Park, M. Lee, J.-H. Kang, R. Shreiner, A. A. High, et al., Nature Nanotechnology 17, 361 (2022).
[29] Guo, Q., et al. Ultrathin quantum light source with van der Waals NbOCl2 crystal. Nature 613 53-59 (2023).
[30] Weissflog, M. A. et al. A Tunable Transition Metal Dichalcogenide Entangled Photon-Pair Source. Nat. Commun., 15, 7600 (2024).
[31] Xu, X. et al. Towards compact phase-matched and waveguided nonlinear optics in atomically layered semiconductors. Nat. Photon. 16 698-706 (2022).
[32] Wang, X.-L. et al. Experimental ten-photon entanglement. Phys. Rev. Lett. 117, 210502 (2016).
[33] Kuznetsov, A. I. et al. Roadmap for Optical Metasurfaces. ACS Photonics 11, 816-865 (2024).
[34] Datta, I. et al. Low-loss composite photonic platform based on 2D semiconductor monolayers. Nat. Photonics. 14, 256-262 (2020).
[35] Bristol, Paesani, S. et al. Generation and sampling of quantum states of light in a silicon chip. Nat. Phys. 15, 925-929 (2019).

What is claimed is:

1. A method for providing at least one periodically-poled layered compound, comprising:
patterning a plurality of slabs of layered compounds; and
stacking the plurality of slabs with each slab twisted relative to each adjacent slab.

2. The method of claim 1, wherein a thickness of the plurality of stacked slabs is less than 1 cm.

3. The method of claim 1, wherein a thickness of the plurality of stacked slabs is up to and including 1 cm.

4. The method of claim 1, wherein one or more interfaces of the stacked slabs provide one or more unique optical microcavities.

5. The method of claim 4, wherein the one or more unique optical microcavities increase a conversion efficiency beyond that achievable with standard phase matching.

6. The method of claim 1, wherein a thickness of each of the plurality of slabs is equal to a length desired for achieving phase matching.

7. A system for providing at least one periodically poled layered compound, comprising:
an electron beam lithography system configured to pattern a plurality of slabs from one or more layered compounds; and
a robotic stacking machine configured to stack the plurality of slabs with each slab being twisted relative to each adjacent slab.

8. The system of claim 7, wherein a thickness of the plurality of stacked slabs is less than 1 cm.

9. The system of claim 7, wherein a thickness of the plurality of stacked slabs is up to and including 1 cm.

10. The system of claim 7, wherein one or more interfaces between the stacked slabs provide one or more unique optical microcavities.

11. The system of claim 10, wherein the one or more unique optical microcavities increase conversion efficiency beyond that achievable with standard phase matching.

12. The system of claim 7, wherein a thickness of each of the plurality of slabs is equal to a length desired for achieving phase matching.

13. A periodically poled layered compound, comprising:
a plurality of slabs of layered compounds, stacked with each slab twisted relative to each adjacent slab.

14. The periodically poled layered compounds of claim 13, wherein a thickness of the plurality of stacked slabs is less than 1 cm.

15. The periodically poled layered compounds of claim 13, wherein a thickness of the plurality of stacked slabs is up to and including 1 cm.

16. The periodically poled layered compounds of claim 13, wherein one or more interfaces of the stacked slabs provide one or more unique optical microcavities.

17. The periodically poled layered compounds of claim 16, wherein the plurality of unique optical microcavities increases conversion efficiency beyond that achievable with standard phase matching.

18. The periodically poled layered compounds of claim 13, wherein a thickness of each of the plurality of slabs is equal to a length desired for achieving phase matching.

19. An apparatus for providing at least one periodically poled layered compound, comprising:
a first system configured to pattern a plurality of slabs from one or more layered compounds; and
a second system configured to stack the plurality of slabs with each slab being twisted relative to each adjacent slab.

20. The apparatus of claim 19, wherein the first system includes a lithography system.

21. The apparatus of claim 20, wherein the lithography system includes an etching capability.

22. The apparatus of claim 20, wherein the lithography system includes an electron beam lithography system.

23. The apparatus of claim 19, wherein the second system includes a stacking machine.

24. The apparatus of claim 20, wherein the stacking machine includes a robotic stacking machine.
